(19) United States
(12) Patent Application Publication
(10) Pub. No.: US 2023/0249118 A1
(43) Pub. Date: Aug. 10, 2023

(54) GAS TREATMENT DEVICE AND VACUUM LINE

(71) Applicant: PFEIFFER VACUUM, Annecy (FR)

(72) Inventor: Emmanuel BEAUJON, Annecy (FR)

(73) Assignee: PFEIFFER VACUUM, Annecy (FR)

(21) Appl. No.: 18/004,632

(22) PCT Filed: Jun. 23, 2021
(86) PCT No.: PCT/EP2021/067230

§ 371 Date: Jan. 6, 2023

(30) Foreign Application Priority Data
Jul. 9, 2020 (FR) 2007250

(51) Int. Cl. B01D 53/04; G08B 21/18; B01D 53/32; B01D 53/82; B01D 53/18

(52) U.S. Cl. CPC B01D 53/0446; G08B 21/182; B01D 53/32; B01D 53/82; B01D 53/18; B01D 2259/818; B01D 2258/0216

(57) ABSTRACT

A gas treatment device treats, at atmospheric pressure, the gases pumped by at least one rough pumping device. The gas treatment device includes a treatment chamber and at least one discharge pipe to connect a discharge of the at least one rough pumping device to an inlet of the treatment chamber. The gas treatment device further includes at least one auxiliary pumping device to lower the pressure in the at least one discharge pipe, situated less than 1 meter from the inlet of the treatment chamber, such as less than 50 cm.

The present invention relates to a gas treatment device and a vacuum line comprising said gas treatment device.

In the semi-conductor, flat panel display and photovoltaic manufacturing industry, manufacturing methods use gases that, after passing through the rough vacuum pumps, are generally treated by gas treatment devices.

Some of these methods are said to be risky, as the gases conveyed in the vacuum lines are flammable and/or explosive. By way of example, mention can be made of hydrogen, silane, TEOS and hydrides.

In addition to these hazardous gaseous species, there can also be deposits of reduced solid species in the vacuum lines, that is, non-oxidized, such as silicon dust or polysilane polymers. These deposits can accumulate over time and promote the emergence of additional hazardous conditions. Some non-oxidized deposits are highly flammable. They can ignite, notably for example due to the sudden pumping of a strong gas stream or simply due to the venting of the pipes or vacuum pumps by the operators during maintenance.

Some explosions can be particularly destructive due to the very large amount of energy released. This is notably the case for chain explosions. A first explosion is firstly initiated by flammable gases. This explosion stirs up deposits of reduced solid species that are potentially present in the pipes. These flammable solid deposits stirred up by the shock wave from the explosion explode in turn in a “super-explosion”.

The risk of personal injury and damage to devices is therefore very high.

The method currently used in response to this problem is to continually dilute the pumped gases with a neutral gas, generally nitrogen. The neutral gas flow rate is determined so that it can respond to the least favourable pumping situations, plus a safety margin.

This solution has a number of drawbacks, however.

Firstly, the significant supply of nitrogen in the vacuum line involves additional costs linked to the gas consumption and also the energy consumption of the vacuum pump, the heating device and the gas treatment device for treating the significant streams of diluted gas. In addition, the cooling of the vacuum lines caused by the dilution of the gases results in other drawbacks, notably due to the cost of the heating elements and the risk of failures. This significant supply of neutral gas also requires the overrating of the gas treatment devices and the rough pumping devices.

The diluent nitrogen additionally results in the formation of nitrogen oxides or “NOₓ”, such as NO₂, in the gas treatment devices. Nitrogen oxides are toxic and constitute atmospheric pollutants that must in turn be treated.

Finally, it has been observed that this solution is reaching its limits as for some recent processes, the increase in diluent gas is becoming insufficient, either because the vacuum pump has insufficient pumping capacity, or because the gas treatment device has insufficient treatment capacity. In these extreme operating conditions, problems relating to the reliability of the vacuum pump or the gas treatment device can arise.

Another solution could be to lower the temperature of the pipes and the vacuum pumps, notably to prevent the thermal decomposition of the precursors and minimize the chemical reactions. However, it is also important to maintain high temperatures in order to prevent risks of deposition by condensation.

Another problem is the tendency of some manufacturing processes, notably in the semi-conductor industry, to use increasingly unstable precursors. The substrate patterns are increasingly thin and the substrates are increasingly thick, that is, they have many layers produced in many process steps. In order to lower the heat balance, which risks damaging the chips of the substrates, new generations of molecule that decompose at lower temperatures are used. The drawback is that they are also deposited more easily in the vacuum line, which can result in significant deposits.

In addition, some used condensable gaseous species can solidify into solid by-products and be deposited, notably in the form of layers, on the moving or static parts of the vacuum pumps or pipes, which can lead to the clogging of the lines.

One aim of the present invention is to increase the safety of the pumping devices and vacuum lines that convey flammable and/or explosive gases. Another aim is to reduce the presence of deposits of condensable species or to delay/minimize the decomposition of precursors that decompose at lower temperatures, in the discharge pipes and in the pumping devices.

To this end, the invention relates to a gas treatment device configured to treat, at atmospheric pressure, the gases pumped by at least one rough pumping device, the gas treatment device comprising a treatment chamber and at least one discharge pipe configured to connect a discharge of the at least one rough pumping device to an inlet of the treatment chamber characterized in that the gas treatment device further includes at least one auxiliary pumping device configured to lower the pressure in the at least one discharge pipe, situated less than 1 metre from the inlet of the treatment chamber, such as less than 50 cm.

Lowering the pressure in the discharge pipe makes it possible to make the vacuum line safe and at the same time prevent deposits of the condensable species in the discharge pipe and in the pumping device, which makes it possible to reduce the heating requirements of the lines. Lowering the heating of the lines makes it possible to prevent thermal decomposition and thus reduce the conversion of the precursors in the pumping device and the kinetics of the chemical activity, which makes it possible to reduce undesirable reactions. Lowering the heating also makes it possible to preserve the quality of the lubricants and improve the reliability of the mechanical parts of the pumping device, notably the bearings. The intervals between maintenance operations can therefore be increased.

In addition, lowering the pressure in the discharge pipe makes it possible to limit the consumption of diluent gas, which also makes it possible to reduce the energy consumption of the pumping device and the gas treatment device and to minimize, or even eliminate, the formation of nitrogen oxides in the gas treatment device.

Lowering the pressure in the vacuum line also reduces the pressure in the rough pumping device, which makes it possible to reduce the size thereof and to use less strong, and therefore cheaper, materials.

The gas treatment device can further include one or more of the features described hereinafter, taken alone or in combination.

The auxiliary pumping device can be mounted in the treatment chamber.

The auxiliary pumping device can include a Venturi gas jet pump mounted in a head of the burner of the treatment chamber.

The gas treatment device can include at least one bypass device interposed between the discharge pipe and the auxiliary pumping device, comprising:
an inlet port connected to the discharge pipe,
a first outlet port connected to the auxiliary pumping device connected to the treatment chamber,
a second outlet port configured to bypass the treatment chamber,
a control member configured to place the inlet port in communication with the first outlet port or the second outlet port.

The bypass device can be a controllable three-way valve.

If the gas treatment device includes at least two bypass devices the first outlet ports of which are connected to the treatment chamber via an auxiliary pumping device, the gas treatment device can include:
at least two isolation valves arranged on the respective discharge of a rough pumping device,
a processing unit connected to the isolation valves and to pressure sensors arranged on the respective discharges of the rough pumping devices downstream of the isolation valves, the processing unit being configured to control the closing of the isolation valves for a predetermined period, apart from one, in order to generate an alert when the measurement from the pressure sensor of the discharge pipe the isolation valve of which is open exceeds a predetermined threshold.

The gas treatment device can include at least one additional auxiliary pumping device connected to at least one second outlet port of the bypass device configured to lower the pressure in said second outlet port.

The gas treatment device can include:
a pressure sensor configured to measure the pressure prevailing in the second outlet port, and
a processing unit connected to the pressure sensor and configured to generate an alert when the pressure measurement exceeds a predetermined threshold.

The gas treatment device can include at least one neutral gas injection device configured to inject a neutral gas into the additional auxiliary pumping device and/or at an outlet of the additional auxiliary pumping device.

The gas treatment device can include a processing unit configured to control the pumping speed of the additional auxiliary pumping device:
to a first speed when no control member places the inlet port in communication with the second outlet port, and
to a second speed when at least one control member places an inlet port in communication with the second outlet port, the second speed being higher than the first speed.

The gas treatment device can include a processing unit configured to control the pumping speed of the additional auxiliary pumping device:
to a first speed when at least one measurement from a pressure sensor of the discharge of a rough pumping device is below or equal to a threshold, and
to a second speed when the measurement exceeds the threshold, the second speed being higher than the first speed.

The gas treatment device can include a processing unit configured to control the pumping speed of the additional auxiliary pumping device:
to a first speed when the concentration of flammable gases or gases capable of causing deposits is below or equal to a predetermined threshold, and
to a second speed when the concentration of flammable gases or gases capable of causing deposits exceeds said threshold, the second speed being higher than the first speed.

The auxiliary pumping device and/or the additional auxiliary pumping device can include a water jet pump and/or a Venturi gas jet pump and/or a liquid ring pump and/or a dry vacuum pump and/or a vane pump.

The treatment chamber can include a burner and/or an electric system and/or a plasma and/or a scrubber and/or a chemisorption and/or physisorption cartridge.

The auxiliary pumping device can include a Venturi gas jet pump the driving gas of which includes a fuel and/or a comburent and/or a neutral gas.

The Venturi gas jet pump can include a heating element configured to heat the driving gas.

The gas treatment device can include a bypass pipe configured to bypass the auxiliary pumping device and/or the additional auxiliary pumping device in the event of overpressure.

The invention also relates to a vacuum line including a gas treatment device as described above.

Further features and advantages of the invention will become apparent from the following description, given by way of non-limiting example, with reference to the appended drawings, in which:

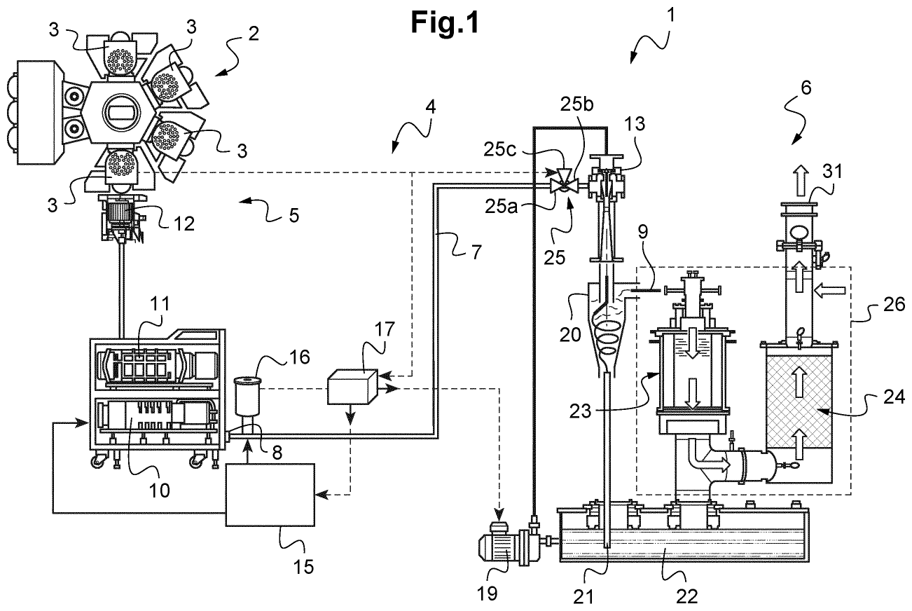

FIG. 1 shows a schematic view of an example of an installation in which only those elements necessary for understanding the invention are shown.

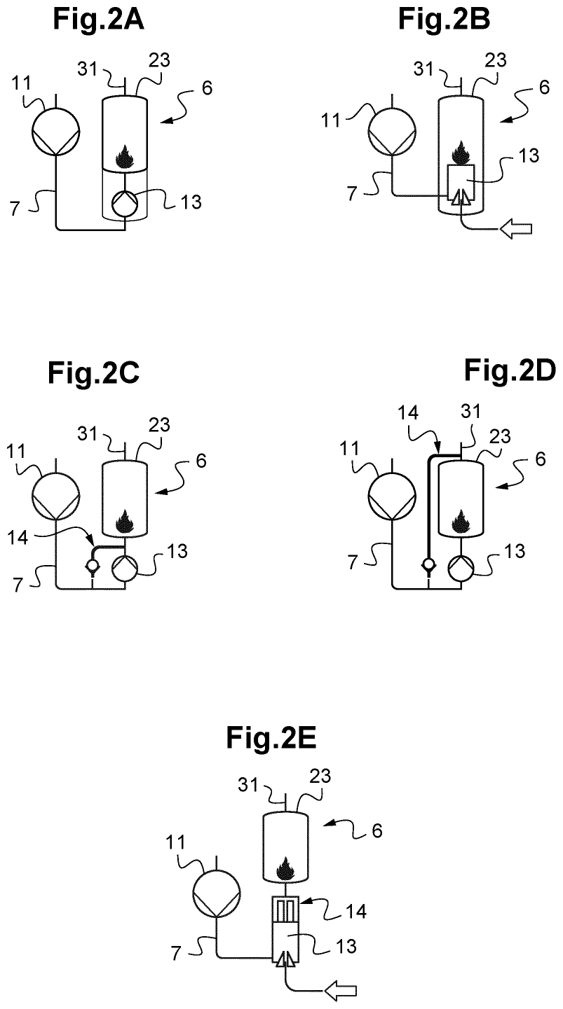

FIG. 2A shows a schematic view of an example of a variant of a vacuum line.

FIG. 2B shows a schematic view of another variant of a vacuum line.

FIG. 2C shows a schematic view of another variant of a vacuum line.

FIG. 2D shows a schematic view of another variant of a vacuum line.

FIG. 2E shows a schematic view of another example of a vacuum line.

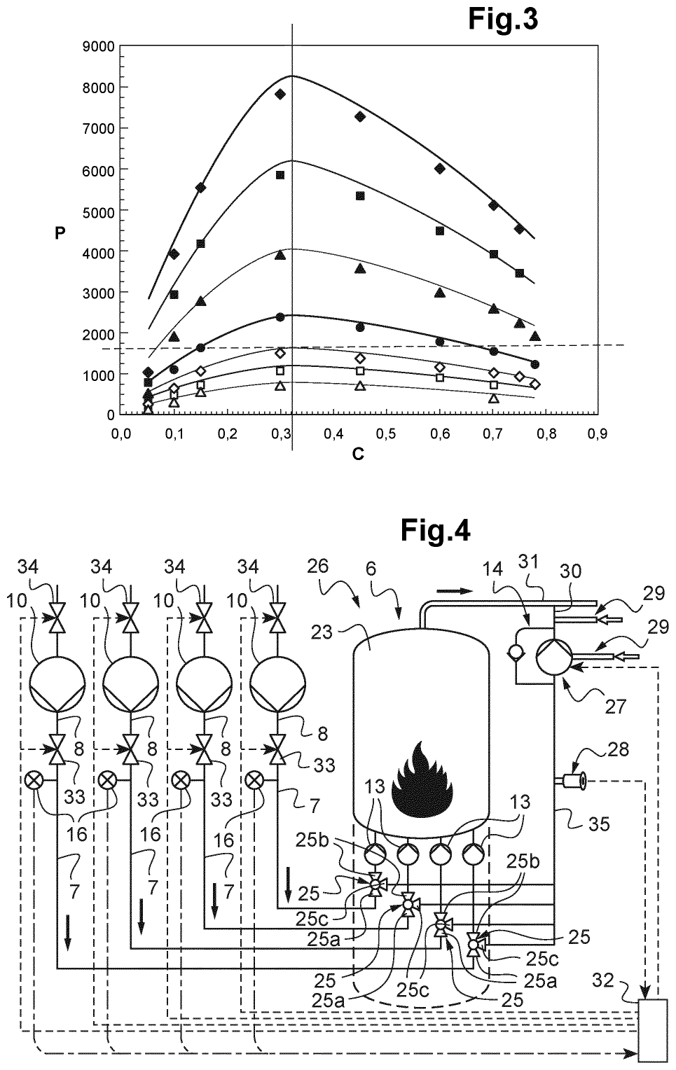

FIG. 3 shows a graph of the explosion pressures in mbar (the symbols represent the measured values and solid lines represent the theoretical values) as a function of the concentration (molecular fraction in the air) of hydrogen for different initial pressure values before explosion: 100 mbar (10,000 Pa) (clear triangles), 150 mbar (15,000 Pa) (solid squares), 200 mbar (20,000 Pa) (clear diamonds), 300 mbar (30,000 Pa) (circles), 500 mbar (50,000 Pa) (solid triangles), 750 mbar (75,000 Pa) (solid squares), 1,000 mbar (100,000 Pa) (solid diamonds).

FIG. 4 shows a schematic view of another example of a vacuum line.

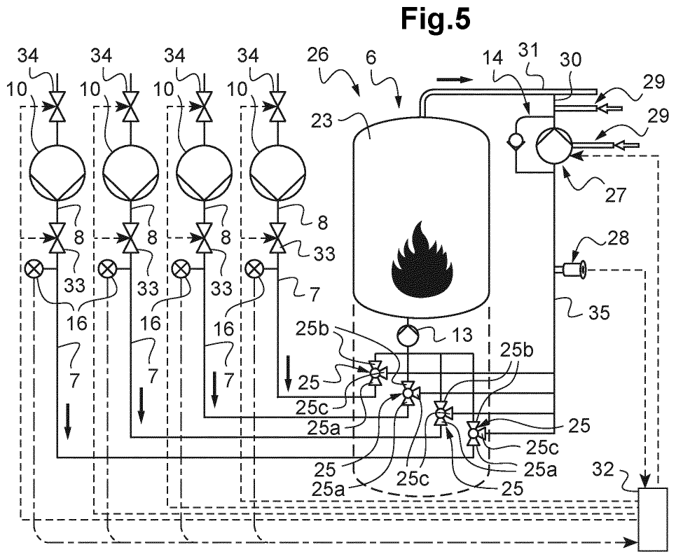

FIG. 5 shows a schematic view of another example of a vacuum line.

In these figures, identical elements bear the same reference numbers.

The following implementations are examples. Although the description refers to one or more embodiments, this does not necessarily mean that each reference relates to the same embodiment or that the features apply only to a single embodiment. Individual features of different embodiments can also be combined or interchanged to provide other embodiments.

Rough vacuum pump is given to mean a positive displacement vacuum pump that is configured to take in, transfer and then discharge a gas to be pumped at atmospheric pressure. The rotors of the rough vacuum pump can be of the Roots, claw, screw, vane or scroll type. A rough vacuum pump is also configured to be able to be started at atmospheric pressure.

A positive displacement vacuum pump configured to take in, transfer and then discharge a gas to be pumped using two Roots rotors is defined as a Roots, or Roots blower, vacuum pump. The Roots vacuum pump is mounted upstream of and in series with a rough vacuum pump. The rotors are held by two shafts rotated by a motor of the Roots vacuum pump.

The Roots vacuum pump mainly differs from the rough vacuum pump in that it has larger pumping stage dimensions due to the higher pumping capacities, and larger tolerances, and in that the Roots vacuum pump cannot discharge at atmospheric pressure, but must be used mounted in series upstream of a rough vacuum pump.

An “upstream” element is given to be one that is positioned before another in relation to the direction of flow of the pumped gases. By contrast, a “downstream” element is given to be one that is positioned after another in relation to the direction of flow of the pumped gases.

An installation 1 includes an apparatus 2 comprising one or more process chambers 3 connected to one or more vacuum lines 4. The process chamber 3 is suitable for receiving one or more substrates, such as a semi-conductor wafer or a flat panel display or a photovoltaic panel.

A vacuum line 4 includes one or more pumping devices 5 connected to at least one process chamber 3, one or more gas treatment devices 6 that include one or more discharge pipes 7 connecting the discharge 8 of at least one rough pumping device 10 to an inlet 9 of a treatment chamber 26 of a gas treatment device 6. By way of example in FIG. 1, a semi-conductor apparatus 2 is shown, a process chamber 3 of which is connected to a vacuum line 4. The discharge pipes 7 can be zo of varying lengths. Between the output of the rough pumping device 10 and the input 9 of the treatment chamber 26, they can have a length of between one and four metres.

The pumping device 5 includes at least one rough pumping device 10, configured to be able to discharge the pumped gases at atmospheric pressure at the discharge 8 or at a pressure greater than atmospheric pressure, notably up to 1,200 mbar (120,000 Pa), the rough pumping device 10 also being capable of discharging the pumped gases at pressures lower than atmospheric pressure.

The pumping device 5 can also include at least one high vacuum pumping device, arranged upstream of and in series with the rough pumping device 10 in the direction of flow of pumped gases, interposed between the process chamber 3 and the rough pumping device 10. The high vacuum pumping device can include a Roots compressor 11 and/or a turbomolecular vacuum pump 12.

The treatment chamber 26 is configured to treat, at atmospheric pressure, the gases pumped by the rough pumping device 10.

In a manner known per se, the treatment chamber 26 includes for example a burner 23 configured to produce thermal reactions at high temperatures by combustion of hydrocarbons and/or an electric system configured to produce thermal reactions at high temperatures by means of heating resistors and/or a plasma and/or a scrubber and/or a chemisorption and/or physisorption cartridge.

According to an exemplary embodiment shown in FIG. 1, the treatment chamber 26 includes a burner 23 and a scrubber 24 arranged in series with and downstream of the burner 23 in the direction of flow of the gases. The burner 23 can be a combustion, electric or plasma burner. A reactive gas, such as oxygen or air, is added to the pumped gases, which are taken to a very high temperature by the burner 23, which activates the formation of new chemically reactive, soluble species that can then be trapped by the scrubber 24. A mist can be generated in the burner 23 by means of water injection nozzles (also commonly known as quench nozzles) in order to cool the gases rapidly and block the chemical equilibria rather than letting the dissociated, hot gases reassociate with each other or react towards an inverted equilibrium. The scrubber 24 includes for example a packed column in which the pumped gases rise in counter-current to a stream of water. At the outlet 31 of the gas treatment device 6, the gases can be discharged into the atmosphere or to a central scrubber of the manufacturing plant.

The gas treatment device 6 further includes at least one auxiliary pumping device 13 configured to lower the pressure in the at least one discharge pipe 7 (FIGS. 1, 4 and 5).

The auxiliary pumping device 13 can be of any type. It includes for example a water jet pump (or water blast) as shown in FIG. 1 and/or a Venturi gas jet pump and/or a liquid ring pump and/or a dry vacuum pump, such as a Roots, claw and/or screw vacuum pump and/or a vane and/or scroll and/or membrane or diaphragm pump.

If the auxiliary pumping device 13 includes a Venturi gas jet pump, the driving gas injected to cause a lowering of the pressure can comprise a neutral gas, such as nitrogen. The driving gas then contributes to further diluting the pumped gases coming from the discharge pipe 7. The driving gas can also include a fuel, such as methane, and/or a comburent. The driving gas then also contributes to further diluting the pumped gases coming from the discharge pipe 7, but without reducing the efficiency of the burner 23 of the gas treatment device 6 and without generating nitrogen oxides.

The Venturi gas jet pump can include a heating element configured to heat the driving gas. The driving gas can be heated, for example to a temperature greater than 50° C., such as greater than 500° C. Heating the driving gas makes it possible to improve the efficiency of the burner 23 of the gas treatment device 6 and makes it possible to prevent the deposition of powder at the jet pump outlet. The driving gas can be heated for example by means of a heat exchanger in contact with hot parts of the treatment chamber 26 or of the pumping device 5, which makes it possible to reduce electricity consumption.

The gas jet pump has the advantage of not consuming electricity. It is compact and light, and can therefore be easily incorporated into the pumping device 5 or into the gas treatment device 6 (FIG. 2A).

If the auxiliary pumping device 13 includes a dry vacuum pump, the purging gas of the auxiliary vacuum pump 13 can include a neutral gas, such as nitrogen, and/or a fuel, such as methane, and/or a comburent. The purging gas can further be heated, for example to a temperature greater than 50° C. such as greater than 500° C., for example by means of a heat exchanger in contact with hot parts of the treatment chamber 26 or of the pumping device 5.

The at least one auxiliary pumping device 13 is situated at the inlet 9 of the treatment chamber 26, that is, at a distance of less than 1 metre, such as less than 50 cm, which generally makes it necessary to raise the auxiliary pumping device 13, as the inlet 9 of the burner is generally positioned more than 1.50 m from the ground.

Generally, the pumping capacity of the auxiliary pumping device 13 is preferably less than the pumping capacity of the rough pumping device 10, such as greater than 5m³/h and/or such as less than 100m³/h. In these conditions, an auxiliary pumping device 13, notably comprising a dry vacuum pump or a liquid ring pump or a vane pump, can be sufficiently light to be able to be positioned as close as possible to the inlet 9 of the treatment chamber 26 (FIG. 2A), for example in the treatment chamber 26 (FIG. 2B) without any risk and without requiring particular handling means.

The Venturi gas jet pump auxiliary pumping device 13 is for example mounted in a head of the burner 23 of the gas treatment device 6 (FIG. 2B). In this case, a single auxiliary pumping device 13 mounted in the treatment chamber 26 can make it possible to lower the pressure in several discharge pipes 7 (FIG. 5). The fuel, comburent of the driving gas, is then the gas supplying the flame of the burner.

The vacuum line 4 can further include at least one bypass pipe 14 configured to bypass the auxiliary pumping device 13 and/or, as will be seen below, the additional auxiliary pumping device 27, in the event of overpressure (FIGS. 2C, 4 and 5).

The bypass pipe 14 includes a pipe bypassing the auxiliary pumping device 13 or the additional auxiliary pumping device 27, and a controllable valve or a check valve, arranged in the pipe and configured to open or close as a function of the pressure difference on either side of the check valve/valve. The bypass pipe 14 makes it possible to bypass the auxiliary pumping device 13 or the additional auxiliary pumping device 27 in order to prevent the pumping capacity restrictions that it can cause, notably in the event of the pumping of strong gaseous streams or in the event of the failure of the auxiliary pumping device 13 or the additional auxiliary pumping device 27.

The bypass pipe 14 can also bypass the gas treatment device 6 (FIG. 2D), but only during the evacuation of volumes of air at atmospheric pressure, without hazardous gaseous species. In this case, the bypass valve 14 is provided with a controllable valve that is normally open, that is, that is open in the absence of a signal or in the event of a fault, and that can only be controlled to close by a dry contact originating from the process chamber 3, when no process gas is introduced into the chamber.

When the auxiliary vacuum pump 13 and/or the additional auxiliary pumping device 27 includes a Venturi gas jet pump, this can be incorporated into the check valve of the bypass pipe 14 (FIG. 2E). The mobile shutter of the check valve then has a Venturi through-passage. The check valve can adopt a closed position in which the check valve forms the jet pump of the auxiliary vacuum pump 13 or of the additional auxiliary pumping device 27 when a driving gas is injected at the inlet of the Venturi passage. The check valve can also adopt an open position in which the pumped gases bypass the Venturi through-passage when the pressure difference on either side of the check valve is greater than a loading threshold of the check valve.

Returning to FIG. 1, it can be seen that the vacuum line 4 can include a diluent gas injection device 15, a pressure sensor 16 configured to measure the pressure prevailing in the discharge pipe 7 and a control unit 17 connected to the pressure sensor 16.

The diluent gas injection device 15 is configured to inject a diluent gas, such as a neutral gas such as nitrogen, into the discharge pipe 7 and/or into the rough pumping device 10 and/or into the auxiliary pumping device 13. The diluent gas is for example injected at the intake and/or discharge 8 of the rough pumping device 10 and/or into the last two pumping stages of a multi-stage rough vacuum pump of the rough pumping device 10.

The pressure sensor 16 is for example arranged at the discharge 8 of the rough pumping device 10.

The control unit 17 includes a controller, microcontroller, memory and computer programs that make it possible to implement a method for controlling the vacuum line. It is for example a computer or a programmable logic controller.

The control unit 17 can be configured to control the auxiliary pumping device 13 and the diluent gas injection device 15 as a function of the pressure measured by the pressure sensor 16 according to a first operating mode or according to a second operating mode.

In the first operating mode, the pressure prevailing in the discharge pipe 7 is maintained at less than or equal to 200 mbar (20,000 Pa).

The auxiliary pumping device 13 that makes it possible to lower the pressure in the discharge pipe 7 can be controlled to pump continuously or intermittently.

For example, the auxiliary pumping device 13 includes a Venturi gas jet pump and the control unit 17 is configured to control the driving gas of the jet pump in order to lower the pressure.

According to another example, the auxiliary pumping device 13 includes a water jet pump and the control unit 17 is configured to control the driving liquid of the water jet pump making it possible to lower the pressure (FIG. 1).

In this case, according to one embodiment, the auxiliary pumping device 13 further includes a hydraulic pump 19, an outlet of which is configured to be controlled by the control unit 17 in order to supply the water jet pump with driving liquid. The inlet of the hydraulic pump 19 is for example placed in communication with a liquid of a bath 22 of the scrubber 24 of the gas treatment device 6. The gas treatment device 6 can then include a gas/water separator 20 interposed between the water jet pump of the auxiliary pumping device 13 and the inlet 9 of the burner 23 of the gas treatment device 6. The liquid residues can be discharged to the bath 22 via a plunger tube 21.

In the first operating mode, which is the optimum operating mode, by default, the pressure is thus maintained below the ignition conditions of most of the flammable gases conveyed in the discharge pipe 7.

This can be better understood with reference to the example in FIG. 3, which shows that for pressures of hydrogen gas of 100 mbar (10,000 Pa), 150 mbar (15,000 Pa) and 200 mbar (20,000 Pa), the explosion pressures under stoichiometric conditions, that is, that can lead to the most severe explosion, remain less than 1,600 mbar (160,000 Pa). A set of safe conditions is thus established in the rough pumping device 10 and in the discharge pipe 7, capable of preventing gas explosions. It is considered that, for a pressure less than or equal to 200 mbar (20,000 Pa), the pressure generated by an ignition (also known as explosion pressure) under stoichiometric conditions can easily be contained, that is, it does not cause significant mechanical damage to the pumping device 5 or the pipework. Although FIG. 3 applies to the specific case of hydrogen, the same behaviours are observed for all flammable gases: the explosion pressures under stoichiometric conditions, that is, that can lead to the most severe explosion, remain below 1,600 mbar (160,000 Pa).

In addition, in the first operating mode, there is no need to inject a diluent gas to be outside the flammability and/or explosion conditions, as safety is ensured by the vacuum level at a pressure of less than 200 mbar (20,000 Pa). The control unit 17 can therefore control the stopping of injection of the diluent gas into the discharge pipe 7 or into the pumping device 5.

Provision can also be made for the control unit 17 to be configured to switch off the injection of the purging gas into the rough pumping device 10 in the first operating mode. It is thus easier to maintain low pressure in the discharge pipe 7.

The control unit 17 can be configured to switch to the second operating mode if it is not possible to lower the pressure to less than 200 mbar (20,000 Pa).

In the second operating mode, the pressure prevailing in the discharge pipe 7 is greater than 20,000 Pa. The control unit 17 is further configured to control the injection of a diluent gas into the discharge pipe 7 or into the pumping device 5 by means of the diluent gas injection device 15. In this second operating mode, which can be seen as a “degraded” operating mode, the risk of flammability can be controlled by dilution.

The control unit 17 can be configured so that the flow rate of the diluent gas introduced into the discharge pipe 7 or the pumping device 5 in the second operating mode is determined as a function of the pressure measured by the pressure sensor 16 so that the pressure generated by an ignition (or explosion pressure) remains less than 160,000 Pa (1,600 mbar) notably under stoichiometric conditions, that is, in the worst flammable gas concentration conditions.

For example, with reference to FIG. 3, it can be seen that when the initial pressure before explosion, measured by the pressure sensor 16, is 300 mbar (30,000 Pa) (circles), the [H₂] concentration of 32% under stoichiometric conditions must be reduced to a target [H₂] concentration, that is, diluted by a neutral gas, of 15%, so that the pressure does not exceed the explosion pressure of 1,600 mbar (160,000 Pa). According to another example in the figure, when the pressure measured by the pressure sensor 16 is 500 mbar (50,000 Pa) (triangles), the concentration under stoichiometric conditions must be reduced to 6-7% by dilution in order to remain below the explosion pressure of 1,600 mbar (160,000 Pa).

The flammable gas concentration before dilution is determined in advance by the user, on the basis of a value of the maximum flow of flammable gases introduced into the process chamber 3.

When there are several flammable gases, the neutral gas dilution rate is determined on the basis of the maximum flow rates of flammable gases injected simultaneously into the process chamber 3.

More specifically, a dilution rate is first determined for each flammable gas separately, using a data table specific to each gas as illustrated by the graph in FIG. 3, as a function of the pressure measured by the pressure sensor 16. The data tables can be stored in the control unit 17. Then, the target, that is diluted, concentrations (to be obtained) of each gas are recalculated for all of the flammable gases introduced simultaneously into the process chamber 3; all of the gases injected simultaneously mutually contribute to lowering their respective concentrations.

The dilution rate is thus adjusted as a function of the quantity (flow, pressure) of flammable/explosive gases so that the pressure generated by an ignition (or explosion pressure) remains below 160,000 Pa (1,600 mbar).

In addition, the diluent gas can include a fuel and/or a neutral gas. The control unit 17 can be configured to determine the quantities and proportions of fuel and neutral gas of the diluent gas as a function of information about the flammable gases introduced into the process chamber 3, such as recipes.

For example, in the case of a recipe that alternates steps of deposition with a TEOS precursor gas and steps of cleaning with an NF₃ gas, the control unit 17, which has access to this information, can increase the quantities of fuel to be injected during the deposition steps, which makes it possible to facilitate the conversion of the TEOS residues into soluble species.

This information can also be used to control the flame temperature of the burner 23.

The control unit 17 can further be configured to control the injection of a high flow rate of diluent gas into the discharge pipe 7 and/or into the pumping device 5 when the pressure measured exceeds 50,000 Pa (500 mbar). This high diluent gas flow rate can be injected as a priority into the pumping device 5 and optionally simultaneously into the discharge pipe 7.

The high diluent gas flow rate is for example predetermined as a function of the maximum flow of flammable gases that can be injected into the process chamber 3. This information is determined in advance by the user, on the basis of a value of the maximum flow of flammable gases introduced into the process chamber. The high diluent gas flow rate is for example predetermined so that the flammable gas concentration is less than 25% of the lower explosive limit (LEL).

The most unfavourable pumping situations are thus made safe, as a function for example of the worst conditions of the recipes implemented in the process chamber 3, plus a safety margin provided by the 25% of the LEL. This is an emergency operating mode, used occasionally in extreme circumstances, similar to permanent practice in the prior art, which resulted in excessive nitrogen consumption in the prior art. Maximum dilution is therefore occasional, which enables savings on diluent gas consumption and on the energy budget.

With reference to FIG. 3, when the hydrogen pressure is greater than 500 mbar (50,000 Pa), the concentration of hydrogen [H₂] can be reduced to values of less than 1% in the discharge pipe 7, that is 25% of the lower explosive limit (LEL) as recommended in the prior art.

In the first operating mode, the control unit 17 thus maintains the pressure in the discharge pipe 7 below 200 mbar (20,000 Pa).

If the pressure measured in the discharge pipe 7 remains below 200 mbar (20,000 Pa), the control unit stays in the first operating mode.

If is it impossible to maintain less than 200 mbar (20,000 Pa) with the auxiliary pumping device 13, notably due to insufficient capacity of the auxiliary pumping device 13, the control unit switches to the second operating mode.

In the second operating mode, the control unit 17 controls the injection of a diluent gas into the discharge pipe 7 or into the pumping device 5.

When the pressure is between 200 mbar (20,000 Pa) and 500 mbar (50,000 Pa), the flow rate of the diluent gas introduced into the discharge pipe 7 or into the pumping device 5 can be determined as a function of the pressure measured by the pressure sensor 16 or as a function of information about the flammable gases introduced into the process chamber 3, so that the explosion pressure remains less than 1,600 mbar (160,000 Pa), in the most severe explosion conditions, such as stoichiometric conditions.

The pressure in the discharge pipe 7 is therefore firstly governed by the capacity of the auxiliary pumping device 13, then by the diluent gas setpoint necessary to dilute the pumped gases as a function of the pressure measured in the discharge pipe 7 and as a function of information about the flammable gases introduced into the process chamber 3, when the pressure measured in the discharge pipe 7 is greater than 200 mbar (20,000 Pa) and less than 500 mbar (50,000 Pa).

If, in the second operating mode, the pressure measured returns to less than 200 mbar (20,000 Pa), then the control unit switches back to the first operating mode.

If the pressure exceeds 500 mbar (50,000 Pa), the diluent gas can be injected, for example directly into the rough pumping device 10, at a predetermined high flow rate value, that is so as to make safe the most unfavourable pumping situations, plus a safety margin.

It will be understood from the above that lowering the pressure in the discharge pipe 7 makes it possible to limit the injection of diluent gas to the most critical situations. As well as making the vacuum line 4 safe, at the same time, lowering the pressure makes it possible to prevent deposits of the condensable species in the discharge pipe 7, which as a result makes it possible to reduce the heating requirements of the lines. In addition, lowering the heating of the lines also makes it possible to avoid thermal decomposition and thus to reduce the conversion of the thermally sensitive precursors in the pumping device 5. This combination of a low pressure and a low temperature also makes it possible to reduce the kinetics of the chemical activity, which makes it possible to reduce undesirable chemical reactions, whether they are corrosive or capable of clogging the elements of the discharge line 4. Lowering the heating also makes it possible to preserve the quality of the lubricants and improve the reliability of the mechanical parts of the pumping device 5, notably the bearings. The intervals between maintenance operations can therefore be significantly increased, which improves the economic profitability of the discharge line 4 and the uptime of the production equipment. Still from an economic point of view, the use of costly noble materials can also be reduced. The elements of the pumping device 5 can be standardized in terms of both design and materials, which simplifies the offering and makes it universal.

In addition, the consumption of diluent gas is limited, which also makes it possible to reduce the energy consumption of the pumping device 5 and, at the same time, of the gas treatment device 6 and to minimize, or even eliminate, the formation of nitrogen oxides in the gas treatment device 6.

According to an exemplary embodiment shown in FIG. 1, the gas treatment device 6 can also include at least one bypass device 25 interposed between the discharge pipe 7 and the auxiliary pumping device 13.

The bypass device 25 comprises an inlet port 25a connected to the discharge pipe 7, a first outlet port 25b connected to the auxiliary pumping device 13 in turn connected to the treatment chamber 26, a second outlet port 25c configured to bypass the treatment chamber 26 and a control member configured to place the inlet port 25a in communication with the first outlet port 25b or the second outlet port 25c. The bypass device 25 is for example a controllable three-way valve.

The bypass device 25 makes it possible to bypass the auxiliary pumping device 13 and the treatment chamber 26, via the second outlet port 25c, only when the pumped gases do not need to be treated. They can thus be directed towards the central scrubber of the manufacturing plant.

The control member can be a manual member. The maintenance operators can operate the control member during maintenance to divert the gases from the treatment chamber 26 during a maintenance operation on the chamber for example. Thus, in the event of the failure or maintenance of the burner 23 for example, the pumped gases can be redirected by the bypass device 25.

The control member can select the first or the second outlet port 25b, 25c, for example as a function of an item of information from the process chamber 3, such as the status of the process chamber 3 (treating, off or on standby) or such as an item of information indicating whether the gases must be treated or not. For example, the gases coming from a process chamber 3 that is off or on standby, can thus not be treated and bypass the burner 23 via the bypass device 25. The information, such as a dry contact or a pneumatic control, can directly control the switching of the control member. There is for example one bypass device 25 per process chamber 3 and several process chambers 3 per apparatus 2.

Several process chambers 3, and therefore several bypass devices 25, can further be connected to a single treatment chamber 26 (FIG. 4). The second outlet ports 25c of the bypass devices 25 can further be associated on a common pipe 35.

The gas treatment device 6 can further include at least one additional auxiliary pumping device 27 connected to at least one second outlet port 25c of the bypass device 25 and configured to lower the pressure in said second outlet port 25c. Lowering the pressure in the second outlet port 25c makes it possible to reduce the rate of chemical reactions, which limits corrosion. In addition, it moves away from the explosion and flammability conditions of the gases. Deposits are reduced, therefore there is less maintenance.

The additional auxiliary pumping device 27 can be of any type. It includes for example a water jet pump and/or a Venturi gas jet pump and/or a liquid ring pump and/or a dry vacuum pump, such as a Roots, claw and/or screw vacuum pump and/or a vane and/or scroll and/or membrane or diaphragm pump.

The outlet 30 of the additional auxiliary pumping device 27 is for example associated with the outlet 31 of the treatment chamber 26 in order to convey the gases to the central scrubber.

The gas treatment device 6 can include a processing unit 32 comprising a controller, microcontroller, memory and computer programs such as a computer or a programmable logic controller. It can be the same unit as the control unit 17 of the vacuum line 4.

According to one exemplary embodiment, the gas treatment device 6 includes a pressure sensor 28 configured to measure the pressure prevailing in the second outlet port 25c. The processing unit 32 can be connected to the pressure sensor 28 and configured to generate an alert when the measurement from the pressure sensor 28 exceeds a predetermined threshold. The predetermined threshold is for example a measurement from the pressure sensor 28 in optimum operating conditions, that is for example taken just after cleaning maintenance. The exceeding of the threshold can reflect an abnormal increase in the pressure in the second outlet port 25c due for example to the clogging of the pipe and/or the presence of a leak in the pipe.

Likewise, the processing unit 32 can be connected to the pressure sensor 16 of the discharge 8 of the rough pumping device 10 and configured to generate an alert when the measurement from the pressure sensor 16 exceeds a predetermined threshold in order to prevent clogging and/or a leak in the discharge pipe 7 connected to the inlet port 25a.

The processing unit 32 can be configured to identify a discharge pipe 7 connected to an inlet port 25a that has a leak or is clogged when several (at least two) bypass devices 25 are connected to the treatment chamber 26.

To this end, the gas treatment device 6 includes at least two isolation valves 33, arranged at the respective discharge 8 of a rough pumping device 10 connected to an inlet port 25a, and can also include at least two isolation valves 34 arranged at a respective inlet of the rough pumping device 10.

The isolation valves 33 are normally open, that is, they are open in the absence of a signal or in the event of a fault. In addition, they can only be controlled to close when no process gas is introduced into the process chamber 3.

The processing unit 32 is connected to the isolation valves 33, to the isolation valves 34 if applicable, and to the pressure sensors 16 of the discharges 8 of the rough pumping devices 10. The pressure sensors 16 are arranged downstream of a respective isolation valve 33.

In normal operating mode, the isolation valves 33, 34 are open.

In diagnostic mode, the processing unit 32 controls the closing of all of the isolation valves 33 for a predetermined period, for example of the order of a few minutes, apart from one, on the discharge pipe 7 the integrity of which is being checked.

The processing unit 32 can also control the closing of the upstream isolation valve 34 and/or the stopping of the rough pumping device 10 and/or switch off the purging gas to the rough pumping device 10.

The processing unit 32 compares the measurement from the pressure sensor 16 of the discharge pipe 7 the isolation valve 33 of which is open to a predetermined threshold. As previously, the predetermined threshold is for example a measurement from the pressure sensor 16 obtained in the same operating conditions after cleaning maintenance. When the measurement from the pressure sensor 16 exceeds the predetermined threshold, the processing unit 32 generates an alert. The test is then reiterated for each discharge pipe 7. It is thus possible to identify whether one of several discharge pipes 7 has a fault.

According to one embodiment, the gas treatment device 6 includes at least one neutral gas injection device 29 configured to inject a neutral gas, such as nitrogen, into the additional auxiliary pumping device 27 and/or at the outlet 30 of the additional auxiliary pumping device 27. The neutral gas makes it possible to dilute the pumped gases to move away from the flammability or explosion conditions.

This neutral gas can be heated before injection, for example to more than 50° C., such as more than 500° C., for example by means of a heat exchanger in contact with the hot parts of the treatment chamber 26. For example, if the additional auxiliary pumping device 27 includes a dry vacuum pump, the neutral gas injection device 29 can be formed by the purging gas of the dry vacuum pump. If the additional auxiliary pumping device 27 includes a Venturi gas jet pump, the neutral gas injection device 29 can be formed by the driving gas.

The additional auxiliary pumping device 27 can be running continually.

According to another example, provision is made to start the additional auxiliary pumping device 27 for example when at least one of the control members of the bypass device 25 places the inlet port 25a in communication with the second outlet port 25c bypassing the treatment chamber 26 and/or as a function of a measurement from the pressure sensor 28 and/or a flammable gas sensor arranged in the common pipe 35 connected to the second outlet ports 25c and/or an item of information coming from the process chamber 3.

The processing unit 32 can be configured to control the pumping speed of the additional auxiliary pumping device 27 as a function of the number of bypass devices placing an inlet port 25a in communication with the common pipe 35 connected to the second outlet ports 25c.

There are for example at least two separate pumping speeds, at least a first and a second speed, the second speed being higher than the first speed.

In the case of a dry vacuum pump additional auxiliary pumping device 27, the second pumping speed is obtained with a rotational speed for example at least 20% higher, or even at least 50% higher than the rotational speed determining the first pumping speed.

This configuration makes it possible to save energy (or driving gas in the case of a jet pump) when little pumped gas is passing through the at least one second outlet port 25c.

The processing unit 32 is for example configured to control the pumping speed to the first speed when no control member places an inlet port 25a in communication with the second outlet port 25c and to control the pumping speed to the second speed when at least one control member places an inlet port 25a in communication with the second outlet port 25c.

According to another example, the processing unit 32 can be configured to control the pumping speed of the additional auxiliary pumping device 27 to the first speed when at least one measurement from a pressure sensor 16 of the discharge 8 of the rough pumping device 10 is below or equal to a predetermined threshold and to the second speed when the measurement exceeds said threshold.

According to another example, the processing unit 32 is configured to control the pumping speed of the additional auxiliary pumping device 27 to a first speed when the concentration of flammable gases or gases capable of causing deposits is below or equal to a predetermined threshold and

to a second speed when the concentration of flammable gases or gases capable of causing deposits exceeds said threshold, the second speed being higher than the first speed.

The concentration of flammable gases or gases capable of causing deposits is for example obtained by means of a gas sensor or information coming from the process chamber 3, notably defined in the recipes of the process. The processing unit 32 increases the pumping speed when the concentration of flammable gases or gases capable of causing deposits increases.

1-20. (canceled)

21. A gas treatment device configured to treat, at atmospheric pressure, gases pumped by at least one rough pumping device, the gas treatment device comprising:
a treatment chamber and at least one discharge pipe configured to connect a discharge of the at least one rough pumping device to an inlet of the treatment chamber,
wherein the gas treatment device further includes at least one auxiliary pumping device configured to lower the pressure in the at least one discharge pipe, situated less than 1 meter from the inlet of the treatment chamber.

22. The gas treatment device according to claim 21, wherein the auxiliary pumping device is mounted in the treatment chamber.

23. The gas treatment device according to claim 21, wherein the auxiliary pumping device includes a Venturi gas jet pump mounted in a head of the burner of the treatment chamber.

24. The gas treatment device according to claim 21, further comprising at least one bypass device interposed between the discharge pipe and the auxiliary pumping device, the at least one bypass device comprising:
an inlet port connected to the discharge pipe,
a first outlet port connected to the auxiliary pumping device connected to the treatment chamber,
a second outlet port configured to bypass the treatment chamber, and
a control member configured to place the inlet port in communication with the first outlet port or with the second outlet port.

25. The gas treatment device according to claim 24, wherein the bypass device is a controllable three-way valve.

26. The gas treatment device according to claim 24, wherein the gas treatment device includes at least two of the bypass device, the first outlet ports of which are connected to the treatment chamber via an auxiliary pumping device,
wherein the gas treatment device includes:
at least two isolation valves arranged on the respective discharge of a rough pumping device,
a processing unit connected to the isolation valves and to pressure sensors arranged on the respective discharges of the rough pumping devices downstream of the isolation valves, the processing unit being configured to control the closing of all of the isolation valves for a predetermined period, apart from one, in order to generate an alert when the measurement from the pressure sensor of the discharge pipe the isolation valve of which is open exceeds a predetermined threshold.

27. The gas treatment device according to claim 24, wherein the gas treatment device includes at least one additional auxiliary pumping device connected to at least one second outlet port of the bypass device and configured to lower the pressure in said second outlet port.

28. The gas treatment device according to claim 27, further comprising:
a pressure sensor configured to measure the pressure prevailing in the second outlet port, and
a processing unit connected to the pressure sensor and configured to generate an alert when the pressure measurement exceeds a predetermined threshold.

29. The gas treatment device according to claim 27, further comprising:
at least one neutral gas injection device configured to inject a neutral gas into the additional auxiliary pumping device and/or at an outlet of the additional auxiliary pumping device.

30. The gas treatment device according to claim 27, further comprising:
a processing unit configured to control the pumping speed of the additional auxiliary pumping device:
to a first speed when no control member places the inlet port in communication with the second outlet port, and
to a second speed when at least one control member places an inlet port in communication with the second outlet port, the second speed being higher than the first speed.

31. The gas treatment device according to claim 27, further comprising:
a processing unit configured to control the pumping speed of the additional auxiliary pumping device:
to a first speed when at least one measurement from a pressure sensor of the discharge of a rough pumping device is below or equal to a threshold, and
to a second speed when the measurement exceeds the threshold, the second speed being higher than the first speed.

32. The gas treatment device according to claim 27, further comprising:
a processing unit configured to control the pumping speed of the additional auxiliary pumping device:
to a first speed when the concentration of flammable gases or gases configured to cause deposits is below or equal to a predetermined threshold, and
to a second speed when the concentration of flammable gases or gases configured to cause deposits exceeds said threshold, the second speed being higher than the first speed.

33. The gas treatment device according to claim 27, wherein the additional auxiliary pumping device includes a water jet pump and/or a Venturi gas jet pump and/or a liquid ring pump and/or a dry vacuum pump and/or a vane pump.

34. The gas treatment device according to claim 27, further comprising:
a bypass pipe configured to bypass the additional auxiliary pumping device in an event of overpressure.

35. The gas treatment device according to claim 21, wherein the auxiliary pumping device includes a water jet pump and/or a Venturi gas jet pump and/or a liquid ring pump and/or a dry vacuum pump and/or a vane pump.

36. The gas treatment device according to claim 21, wherein the treatment chamber includes a burner and/or an electric system and/or a plasma and/or a scrubber and/or a chemisorption and/or physisorption cartridge.

37. The gas treatment device according to claim 21, wherein the auxiliary pumping device includes a Venturi gas jet pump, a driving gas of which includes a fuel and/or a comburent and/or a neutral gas.

38. The gas treatment device according to claim 37, wherein the Venturi gas jet pump includes a heating element configured to heat the driving gas.

39. The gas treatment device according to claim 21, further comprising:
a bypass pipe configured to bypass the auxiliary pumping device in an event of overpressure.

40. A vacuum line comprising:
at least one of the gass treatment device according to claim 21.
